(19) United States
(12) Patent Application Publication
(10) Pub. No.: US 2013/0068614 A1
(43) Pub. Date: Mar. 21, 2013

(54) SPUTTER DEPOSITION APPARATUS

(71) Applicant: ULVAC, INC., Chigasaki-shi (JP)

(72) Inventors: Tatsunori Isobe, Sammu-shi (JP); Tetsuhiro Ohno, Chigasaki-shi (JP); Shigemitsu Sato, Chigasaki-shi (JP); Tomokazu Suda, Sammu-shi (JP)

(73) Assignee: ULVAC, INC., Chigasaki-shi (JP)

(21) Appl. No.: 13/688,731

(22) Filed: Nov. 29, 2012

Related U.S. Application Data
(63) Continuation of application No. PCT/JP2011/062666, filed on Jun. 2, 2011.

(30) Foreign Application Priority Data
Jun. 3, 2010 (JP) 2010-128343

(51) Int. Cl. C23C 14/35

(52) U.S. Cl. CPC C23C 14/35
USPC 204/298.13; 204/298.16

(57) ABSTRACT

A sputter deposition apparatus can sputter the entire sputtering surface of a target, and thereby increase the usage efficiency of the target and prevent arcing. An adhesion-preventing member, which surrounds the outer periphery of a sputtering surface of an electrically-conductive target 21₁, is formed by insulating ceramic. The target is sputtered in a reaction gas atmosphere while moving a magnet device between a position where the entire outer periphery of an outer peripheral magnet is on the inside of the outer periphery of the sputtering surface and a position where a part of the outer periphery of the outer peripheral magnet protrudes to the outside of the outer periphery of the sputtering surface. Since the entire sputtering surface of the target is sputtered, an insulating compound does not accumulate on the target and arcing does not occur.

This application is a continuation of International Application No. PCT/JP2011/062666, filed on Jun. 2, 2011, which claims priority to Japan Patent Application No. 2010-128343, filed on Jun. 3, 2010. The contents of the prior applications are herein incorporated by reference in their entireties.

### BACKGROUND

The present invention is generally related to a sputter deposition apparatus, and more particularly to the technical field of forming a SiO₂ thin film by sputtering a Si target in O₂ gas ambience.

SiO₂ thin films are used in protective films for channel layers of thin film transistors (TFTs) and barrier films for float glass. Recently, as a method for forming a SiO₂ thin film on an object to be film-deposited which becomes a large surface area, reactive sputtering is generally carried out by sputtering a Si target while chemically reacting it in an O₂ gas atmosphere.

FIG. 8 is a cross-sectional view of an internal structure of a conventional sputter deposition apparatus 110.

The sputter deposition apparatus 110 includes a vacuum chamber 111 and a plurality of sputter units 120₁ to 120₄. The sputter units 120₁ to 120₄ have the same structure. The following explanation uses the sputter unit associated with reference numeral 120₁ as a representative example. The sputter unit 120₁ includes a target 121₁, a backing plate 122₁, and a magnet device 126₁.

Here, the target 121₁ is Si, and is formed into a flat planar shape that is smaller than the surface of the backing plate 122₁. The entire outer periphery of the target 121₁ is positioned on the inside of the outer periphery of the surface of the backing plate 122₁, and the target 121₁ is stacked upon and affixed to the surface of the backing plate 122₁ in a manner such that the peripheral edge of the surface of the backing plate 122₁ is exposed from the outer periphery of the target 121₁.

The magnet device 126₁ is disposed on the rear surface side of the backing plate 122₁. The magnet device 126₁ includes a center magnet 127b₁ disposed linearly on a magnet fixing plate 127c₁ that is parallel to the backing plate 122₁, and an outer peripheral magnet 127a₁ which surrounds the center magnet 127b₁ in a ring shape at a predetermined distance from the peripheral edge of the center magnet 127b₁. The outer peripheral magnet 127a₁ and the center magnet 127b₁ are respectively disposed in a manner such that their magnetic poles of difference polarities face toward the rear surface of the target 121

A moving device 129 is disposed on the underside of the magnet device 126₁; and the magnet device 126₁ is attached to the moving device 129. The moving device 129 is configured to move the magnetic device 126₁ in a direction parallel to the rear surface of the target 121₁.

The overall structure of the sputter deposition apparatus 110 will now be explained. The backing plates 122₁ to 122₄ of the sputter units 120₁ to 120₄ are arranged in a line spaced apart from each other on a wall surface on the inside of the vacuum chamber 111. The backing plates 122₁ to 122₄ are attached to the wall surface of the vacuum chamber 111 via insulators 114, and electrically insulated with the vacuum chamber 111.

On the outside of the outer periphery of the backing plates 122₁ to 122₄, adhesion-preventing members 125 made of metal are disposed upright at a distance from the outer periphery of the backing plates 122₁ to 122₄ and are electrically connected to the vacuum chamber 111. The ends of the adhesion-preventing members 125 are bent at a right angle toward the outer peripheries of the targets 121₁ to 121₄ so as to cover the peripheral edges of the backing plates 122₁ to 122₄, and surround the surfaces of the targets 121₁ to 124₄ in a ring shape. Portions on the surface of the targets 121₁ to 121₄, which are exposed in the inner periphery of the ring of the adhesion-preventing members 125, are referred to as sputtering surfaces.

A vacuum evacuation device 112 is connected to an exhaust opening of the vacuum chamber 111; and the inside of the vacuum chamber 111 is evacuated. An object to be film-deposited 131 is mounted on an object holder 132, carried into the vacuum chamber 111, and held stationary at a position separated from and facing the sputtering surfaces of the targets 121₁ to 121₄.

A gas introduction system 113 is connected to an inlet of the vacuum chamber 111 and a mixed gas of Ar gas as a sputtering gas and O₂ gas as a reaction gas into the vacuum chamber 111. The O₂ gas reacts with the surfaces of the targets 121₁ to 121₄ so as to form the SiO₂ as oxide.

A power source device 135 is electrically connected to the backing plates 122₁ to 122₄. When alternating current (AC) voltages which have mutually opposite polarities are applied to two adjacent targets, the targets enter a state in which one of the two adjacent targets is brought to a positive potential when the other is brought to a negative potential. Electrical discharge is generated between the adjacent targets, and the Ar gas between the targets 121₁ to 121₄ and the object to be film-deposited 131 is plasmatized.

Alternatively, the following constitution is also possible: the power source device 135 is electrically connected to the backing plates 122₁ to 122₄ and the object to be film-deposited retainer 132, AC voltages having reverse polarities are applied to the targets 121₁ to 121₄ and the object to be film-deposited 131; and electrical discharge is generated between the targets 121₁ to 121₄ and the object to be film-deposited 131; and then, the Ar gas between the targets 121₁ to 121₄ and the object to be film-deposited 131 is plasmatized. In this case, this method can also be carried out using a single target.

The Ar ions in the plasma are trapped in the magnetic fields formed by the magnet devices 126₁ to 126₄ on the surfaces of the targets 121₁ to 121₄ which is the opposite side of the backing plates 122₁ to 122₄. When the targets 121₁ to 121₄ are brought to a negative potential, the Ar ions collide into the sputtering surfaces of the targets 121₁ to 121₄ and hit off particles of SiO₂. A part of the SiO₂ which is hit off adheres to the surface of the object to be film-deposited 131.

The magnetic fields generated on the targets 121₁ to 121₄ are non-uniform due to the structure of the magnet devices 126₁ to 126₄ as described above. Therefore, the Ar ions aggregate at portions of relatively high magnetic density and the targets 121₁ to 121₄ are scraped away at these portions quickly compared to surrounding portions of relatively low magnetic density. In order to prevent the occurrence of such portions (erosions) where the targets 121₁ to 121₄ are locally scraped away as discussed above, sputtering is carried out while moving the magnet devices 126₁ to 126₄. However, when plasma trapped in the magnetic fields is in contact with the electrically-grounded adhesion-preventing members 125, abnormal discharge (arcing) frequently occurs so that it is necessary to move the magnet devices 126₁ to 126₄ within a range in which the entire outer peripheries of the rings of the outer peripheral magnets 127a₁ to 127a₄ are positioned on the inside of the outer peripheries of the sputtering surfaces.

Thus, plasma does not reach the outer edges of the targets 121₁ to 121₄ and areas which are not sputtered (non-erosion areas) are formed. Insulating SiO₂ accumulates on the non-erosion areas of the targets 121₁ to 121₄ and on the surfaces of the adhesion-preventing members 125 to form insulating thin films. This has been a problem because electrical charge builds up on the insulating thin films, and it makes the insulating thin films to cause insulation breakdown at locations where the electrical charge amount exceeds a certain threshold; and thus, electrical current suddenly flows to the targets 121₁ to 121₄ and causes abnormal discharge (arcing) (see, for example, JPAH04-210471).

### SUMMARY OF THE INVENTION

The present invention was created in order to solve the disadvantages of the above-described prior art; and an object thereof is to provide a sputter deposition apparatus which can increase the usage efficiency of a target by sputtering the entire sputtering surface of the target as well as prevent the occurrence of arcing.

In order to solve the above problem, the present invention provides a sputter deposition apparatus including a vacuum chamber, a vacuum evacuation device evacuating the inside of the vacuum chamber, a gas introduction system introducing gas into the vacuum chamber, a target having a sputtering surface exposed inside the vacuum chamber, an adhesion-preventing member disposed inside the vacuum chamber and provided to the target so as to surround a periphery of the sputtering surface of the target, a magnet device arranged on a rear surface side opposite to the sputtering surface of the target, a power source device applying a voltage to the target, and a moving device which moves the magnet device in a direction parallel to the rear surface of the target. The magnet device has a ring-shaped outer peripheral magnet which faces toward the rear surface of the target and a center magnet disposed on the inside of the ring formed by the outer peripheral magnet; a polarity of a magnetic pole of a portion at which the outer peripheral magnet faces toward the rear surface of the target and a polarity of a magnetic pole of a portion at which the center magnet faces toward the rear surface of the target are different from each other; the adhesion-preventing member is formed of an insulating ceramic; and the moving device moves the magnet device between a position where the entire outer periphery of the outer peripheral magnet is on the inside of the outer periphery of the sputtering surface and a position where a part of the outer periphery of the outer peripheral magnet protrudes to the outside of the outer periphery of the sputtering surface.

The present invention also provides the sputter deposition apparatus wherein the target is Si, and the gas introduction system has an O₂ gas source which releases O₂ gas.

Furthermore, the present invention is the sputter deposition apparatus further including a plurality of sputter units which include the target, the adhesion-preventing member provided to the target, and the magnet device disposed on the rear surface side of the target. The targets of the sputter units are arranged in a line spaced apart from each other, each sputtering surface being oriented toward an object to be film-deposited carried into the vacuum chamber; the power source device is configured to apply a voltage to the target of each sputter unit; and the moving device moves the magnet device of one sputter unit between a position where the entire outer periphery of the outer peripheral magnet of the magnet device is on the inside of the outer periphery of the sputtering surface of the target of the sputter unit and a position where a part of the outer periphery of the outer peripheral magnet protrudes out between the outer periphery of the sputtering surface of the target and the outer periphery of the sputtering surface of the target of another sputter unit adjacent to the target.

Since sputtering can be carried out across the entire sputtering surface of the target, the usage efficiency of the target can be improved and the life of the target can be extended.

Since insulant does not accumulate on the electrically-conductive target, arcing does not occur, damage to the target due to arcing can be prevented, and contamination due to impurities in the thin film to be formed can be prevented.

Since the space between the outer peripheries of adjacent targets can be widened, the amount of target material to be used can be reduced; and thus, the cost can be reduced.

### BRIEF DESCRIPTION OF THE DRAWINGS

FIG. 1 is an internal structure view of a sputter deposition apparatus of the present invention.

FIG. 2 is a cross-sectional view along line A-A of FIG. 1 of the sputter deposition apparatus of the present invention.

FIG. 3 is a cross-sectional view along line B-B of FIG. 1 of the sputter deposition apparatus of the present invention.

FIG. 4 is an internal structure view of a second embodiment of a sputter deposition apparatus of the present invention.

FIGS. 5(a) and 5(b) are schematic views showing a cross-section of a sputter unit during sputtering.

FIG. 6 is a picture showing a corner portion of a target surface after sputtering in a conventional sputter deposition apparatus.

FIG. 7 is a picture showing a corner portion of a target surface after sputtering in the sputter deposition apparatus of the present invention.

FIG. 8 is a cross-sectional view of an internal structure of a conventional sputter deposition apparatus.

### DETAILED DESCRIPTION OF THE INVENTION

The structure of the sputter deposition apparatus of the present invention will now be explained.

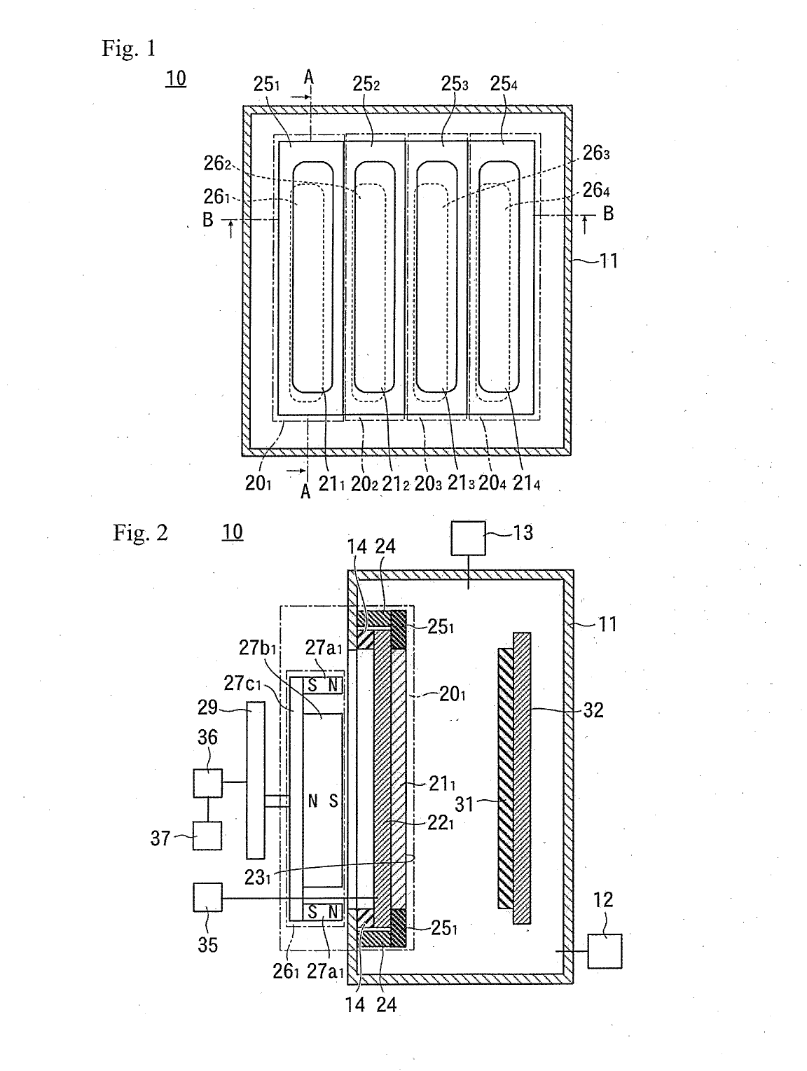

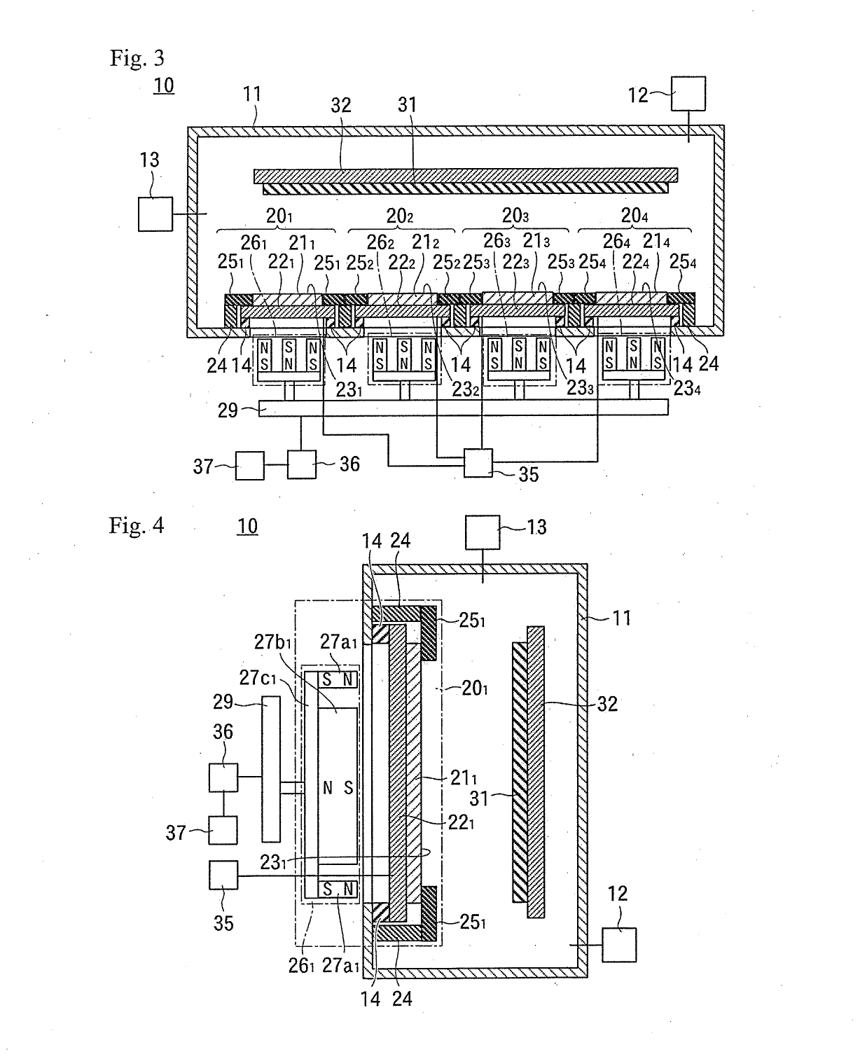

FIG. 1 is an internal structure view of a sputter deposition apparatus 10; FIG. 2 is a cross-sectional view along line A-A of FIG. 1, and FIG. 3 is a cross-sectional view along line B-B of FIG. 1.

The sputter deposition apparatus 10 includes a vacuum chamber 11 and a plurality of sputter units 20₁ to 20₄.

The structure of the sputter units 20₁ to 20₄ is the same. The following explanation uses the sputter unit associated with reference numeral 20₁ as a representative example.

The sputter unit 20₁ includes a target 21₁ having a sputtering surface 23₁ which is exposed inside the vacuum chamber 11 to be sputtered, a backing plate 22₁, an adhesion-preventing member 25₁ which is disposed inside the vacuum chamber 11 and provided to the target 21₁ so as to surround the sputtering surface 23₁ of the target 21₁, and a magnet device 26₁ disposed on a rear surface side, which is the opposite side of the sputtering surface 23₁ of the target 21₁.

The target 21₁ is an electrically-conductive material (such as, Si), which forms an insulating compound when reacted with oxygen or nitrogen.

The target 21₁ is formed into a flat planar shape and the surface of the target 21₁ is smaller than the surface of the backing plate 22₁. The entire outer periphery of the target 21₁ is positioned on the inside of the outer periphery of the backing plate 22₁, and the target 21₁ is stacked upon and affixed to the surface of the backing plate 22₁ in a manner such that the entire periphery at the peripheral edge of the backing plate 22₁ is exposed from the outer periphery of the target 21₁.

The adhesion-preventing member 25₁ is made of insulating ceramic and has a ring shape. A “ring shape” as used herein refers to a shape surrounding the periphery of the sputtering surface 23₁ of the target 21₁, and does not necessarily mean a seamless circular ring. In other words, as long as it surrounds the periphery of the sputtering surface 23₁ of the target 21₁, any shape is sufficient, and the ring can include a plurality of parts and have a linear shape at a certain portion thereof.

As shown in FIG. 2, the outer periphery of the ring of the adhesion-preventing member 25₁ is larger than the outer periphery of the backing plate 22₁, and the inner periphery of the ring is the same as or larger than the outer periphery of the target 21₁.

The adhesion-preventing member 25₁ is disposed on the surface of the backing plate 22₁ where the target 21₁ is fixed at a relative position in a manner such that the center of the ring of the adhesion-preventing member 25₁ overlaps with the center of the target 21₁, so as to cover the exposed peripheral edge of the backing plate 22₁ and surround the outer periphery of the target 21₁ with the inner periphery of the ring of the adhesion-preventing member 25₁.

The inner periphery of the ring of the adhesion-preventing member 25₁ is preferably as small as possible so that plasma (to be explained later) does not invade into the gap between the inner periphery of the ring of the adhesion-preventing member 25₁ and the outer periphery of the target 21₁.

Among the two surfaces of the target 21₁, the surface which is closely adhered to the backing plate 22₁ is referred as the rear surface and the opposite surface is referred as the top surface, while the entire top surface of the target 21₁ is exposed on the inside of the ring of the adhesion-preventing member 25₁, and the entire top surface of the target 21₁ is the sputtering surface to be sputtered. Reference numeral 23₁ refers to the sputtering surface.

In other words, the adhesion-preventing member 25₁ is disposed at the ends of the target 21₁, in which the surface of the target 21₁ that includes the sputtering surface 23₁ becomes discontinuous, so as to surround the periphery of the sputtering surface 23₁.

The adhesion-preventing member 25₁ of the present invention is not limited to a case in which the inner periphery of the ring of the adhesion-preventing member 25₁ is the same or larger than the outer periphery of the target 21₁. As shown in FIG. 4, a case in which the inner periphery of the ring of the adhesion-preventing member 25₁ is smaller than the outer periphery of the target 21₁ is also included to the present invention. In this case, when the adhesion-preventing member 25₁ is disposed on the top surface of the target 21₁ as described above, the adhesion-preventing member 25₁ covers the peripheral edge of the target 21₁; and thus, the portion of the top surface of the target 21₁ exposed inside the ring of the adhesion-preventing member 25₁ is the sputtering surface 23₁.

The magnet device 26₁ is disposed on the rear surface side of the backing plate 22₁, or in other words, it is disposed on the rear surface side of the target 21₁.

The magnet device 26₁ has a ring-shaped outer peripheral magnet 27a₁ which faces toward the underside of the target 21₁ and a center magnet 27b₁ which is disposed on the inside of the ring which is formed by the outer peripheral magnet 27a₁. A “ring shape” as used herein refers to a shape surrounding the periphery of the center magnet 27b₁, and does not necessarily mean a seamless circular ring. In other words, as long as it surrounds the periphery of the center magnet 27b₁, any shape is sufficient, and the ring can include of a plurality of parts and have a linear shape at a certain portion thereof. The shape can also be a closed circular ring or a shape in which a circular ring is deformed while closed.

In other words, the magnet device 26₁ has a center magnet 27b₁ that is disposed at an orientation so as to generate a magnetic field on the sputtering surface 23₁ and an outer peripheral magnet 27a₁ that is disposed in a continuous shape on the periphery of the center magnet 27b₁.

The center magnet 27b₁ is disposed linearly (herein) on a magnet fixing plate 27c₁ which is parallel to the backing plate 22₁, and the outer peripheral magnet 27a₁ disposed on the magnet fixing plate 27c₁ surrounds the center magnet 27b₁ in a ring shape at a predetermined distance from the peripheral edge of the center magnet 27b₁.

In other words, the outer peripheral magnet 27a₁ has a ring shape; the center axis line of the ring of the outer peripheral magnet 27a₁ is oriented to vertically intersect the rear surface of the target 21₁; and the center magnet 27b₁ is disposed on the inside of the ring of the outer peripheral magnet 27a₁.

The outer peripheral magnet 27a₁ and the center magnet 27b₁ are respectively disposed in a manner such that their magnetic poles of different polarities face toward the rear surface of the target 21₁. That is, a polarity of the magnetic pole of a portion at which the outer peripheral magnet 27a₁ faces toward the rear surface of the target 21₁ and a polarity of the magnetic pole of a portion at which the center magnet 27b₁ faces toward the rear surface of the target 21₁ are different from each other.

The overall structure of the sputter deposition apparatus 10 will now be explained. The backing plates 22₁ to 22₄ of the sputter units 20₁ to 20₄ are arranged in a line spaced apart from each other on a wall surface on the inside of the vacuum chamber 11 so that the rear surfaces of the backing plates 22₁ to 22₄ faces toward the wall surface.

The backing plates 22₁ to 22₄ of the sputter units 20₁ to 20₄ are attached to the wall surface of the vacuum chamber 11 via columnar insulators 14; and the backing plates 22₁ to 22₄ of the sputter units 20₁ to 20₄ and the vacuum chamber 11 are electrically insulated.

Columnar support members 24 are disposed upright on the outside of the outer periphery of the backing plates 22₁ to 22₄ of the sputter units 20₁ to 20₄; and the adhesion-preventing members 25₁ to 25₄ of the sputter units 20₁ to 20₄ are fixed on the top ends of the support members 24.

If the support members 24 are electrically conductive, the support members 24 are spaced apart from the outer periphery of the backing plates 22₁ to 22₄ of the sputter units 20₁ to 20₄. The electrically-conductive support members 24 are electrically connected to the vacuum chamber 11, however, since the adhesion-preventing members 25₁ to 25₄ are insulating, so that the backing plates 22₁ to 22₄ and the vacuum chamber 11 are electrically insulated even if the adhesion-preventing members 25₁ to 25₄ make contact with the backing plates 22₁ to 22₄.

A power source device 35 is electrically connected to the backing plates 22₁ to 22₄ of the sputter units 20₁ to 20₄. The power source device 35 is configured to apply AC voltages (herein) to the backing plates 22₁ to 22₄ of the sputter units 20₁ to 20₄ in a manner such that the AC voltages are shifted by half a period between two adjacent targets (a so-called AC sputtering method). When AC voltages having reverse polarities are applied to two adjacent targets, when one of the two adjacent targets is brought to a positive potential, the other is brought to a negative potential, so that electrical discharge is generated between the adjacent targets. If the frequency of the AC voltages is in the range of 20 kHz to 70 kHz (20 kHz or greater to 70 kHz or less), the electrical discharge between the adjacent targets can be stabilized and maintained; and thus, a frequency in this range is preferable, and a frequency of 55 kHz is more preferable.

The power source device 35 of the present invention is not limited to a structural arrangement in which it applies AC voltages to the backing plates 22₁ to 22₄ of the sputter units 20₁ to 20₄; and the power source device 35 can apply pulsed negative voltages multiple times. In this case, the power source device 35 is configured to apply a negative voltage to one target among the two adjacent targets after completing an application of a negative voltage to the other target and before beginning to apply the next negative voltage to the other target.

Alternatively, a power source device 35, which is an AC power source, can be electrically connected to the backing plates 22₁ to 22₄ of the sputter units 20₁ to 20₄ and an object holder 32 (to be explained later); and AC voltages having reverse polarities can be applied to the targets 21₁ to 21₄ and object to be film-deposited 31 (a so-called RF sputtering method). When the predetermined voltages are respectively applied to the backing plates 22₁ to 22₄ and the object holder 32 from the power source device 35, electrical discharge is generated between the targets 21₁ to 21₄ and the object to be film-deposited 31.

The RF sputtering method can be carried out even in the case in which a single target is used; and thus, the RF sputtering method is advantageous compared to the AC sputtering method.

A moving device 29, which is an XY stage, is disposed on the rear surface side of the magnet fixing plates 27c₁ to 27c₄ of the magnet devices 26₁ to 26₄ of the sputter units 20₁ to 20₄; and the magnet devices 26₁ to 26₄ are attached to the moving device 29. A control device 36 is connected to the moving device 29, and the moving device 29 is configured to move the magnet devices 26₁ to 26₄ of the sputter units 20₁ to 20₄ in two directions (the X-axis direction and the Y-axis direction) parallel to the rear surface of the targets 21₁ to 21₄ of the sputter units 20₁ to 20₄ when a control signal is received from the control device 36.

The structures of the sputter units 20₁ to 20₄ are the same. The following explanation uses the sputter unit associated with reference numeral 20₁ as a representative example. A storage device 37, in which a position where a part of the outer periphery of the outer peripheral magnet 27a₁ protrudes to the outside of the outer periphery of the sputter surface 23₁ is stored, is connected to the control device 36. The protruding position is defined relative to the movement axes of the X-axis and the Y-axis.

The control device 36 is configured to make the magnet device 26₁ move between a position where the entire outer periphery of the outer peripheral magnet 27a₁ is on the inside of the outer periphery of the sputtering surface 23₁ of the target 21₁ and the protruding position stored in the storage device 37. If a position at which a part of the outer periphery of the outer peripheral magnet 27a₁ protrudes out by a distance longer than a protruding minimum value (to be explained later) is stored in the storage device 37, in the course of repeating such a movement, each point just under every point of the entire sputtering surface 23₁ faces the surface of the outer peripheral magnet 27a₁ at least once, and the outer periphery of the outer peripheral magnet 27a₁ intersects every portion over the entire outer periphery of the sputtering surface 23₁ at least once.

As will be discussed later, when a portion of the outer periphery of the outer peripheral magnet 27a₁ protrudes out toward the outside of the outer periphery of the sputtering surface 23₁ during sputtering, plasma trapped in the magnetic field formed by the magnet device 26₁ is in contact with the adhesion-preventing member 25₁. However, because the adhesion-preventing member 25₁ is made of an insulating ceramic, abnormal discharge is not generated even if the plasma is in contact with the adhesion-preventing member 25₁ so that the entire sputtering surface 23₁ is sputtered. Therefore, compared to a conventional apparatus, the usage efficiency of the target 21₄ can be improved and the life of the target 21₁ can be extended.

In terms of the relationship between one sputter unit (for example, reference numeral 20₁) among the sputter units 20₁ to 20₄ and another sputter unit 20₂ that is adjacent thereto, the control device 36 is configured to make the magnet device 26₁ of the one sputter unit 20₁ move between a position where the entire outer periphery of the outer peripheral magnet 27a₁ of the magnet device 26₁ is on the inside of the outer periphery of the sputtering surface 23₁ of the target 21₁ of the sputter unit 20₁ and another position where apart of the outer periphery of the outer peripheral magnet 27a₂ protrudes out between the outer periphery of the sputtering surface 23₁ and the outer periphery of the sputtering surface 23₂ of the target 21₂ of the other sputter unit 20₂ adjacent to the target 21₁.

In other words, if the area between the outer periphery of the sputtering surface 23₁ of the target 21₁ of the sputter unit 20₁ and the outer periphery of the sputtering surface 23₂ of the target 21₂ of the other sputter unit 20₂ adjacent to the sputter unit 20₁ is referred to as the outside area, the control device 36 is configured to make the magnet device 26₁ of the sputter unit 20₁ move between a position where the entire outer periphery of the outer peripheral magnet 27a₁ of the magnet device 26₁ is on the inside of the outer periphery of the sputtering surface 23₁ of the target 21₁ of the sputter unit 20₁ and another position where a part of the outer periphery of the outer peripheral magnet 27a₁ protrudes out into the outside area.

In other words, the magnet device 26₁ disposed on the underside of the sputtering surface 23₁ of at least one target 21₁ is configured to move between a position where the entire outer periphery of the outer peripheral magnet 27a₁ is on the inside of the inner periphery of the adhesion-preventing member 25₁ surrounding the periphery of the sputtering surface 23₁ of the target 21₁ and another position where a part of the outer periphery of the outer peripheral magnet 27a₁ protrudes out between the outside of the inner periphery of the adhesion-preventing member 25₁ of the target 21₁ and the inner periphery of the adhesion-preventing member 25₂ that surrounds the periphery of the sputtering surface 23₂ of the other target 21₂ adjacent to the target 21₁.

Therefore, in the present invention, if the size of the sputtering surfaces 23₁ to 23₄ of the targets 21₁ to 21₄ of the sputter units 20₁ to 20₄ is the same as in a conventional apparatus, and the width between the outer periphery of the erosion area to be sputtered of the sputtering surface 23₁ of the target 21₁ of one sputter unit (here, reference number 20₁) and the outer periphery of the erosion area of the sputtering surface 23₂ of the target 21₂ of another sputter unit 20₂ which is adjacent is the same as that in a conventional apparatus, the gaps between the outer peripheries of the adjacent targets 21₁ to 21₄ can be made wider than that in a conventional apparatus. Therefore, compared to a conventional apparatus, the amount of target material to be used can be reduced; and thus, the cost can be reduced.

An exhaust opening is provided on the wall surface of the vacuum chamber 11, and a vacuum evacuation device 12 is connected to the exhaust opening. The vacuum evacuation device 12 is configured to evacuate the inside of the vacuum chamber 11 from the exhaust opening.

An inlet is also provided on the wall surface of the vacuum chamber 11; and a gas introduction system 13 is connected to the inlet. The gas introduction system 13 has a sputtering gas source which releases sputtering gas and a reaction gas source which releases reaction gas reacting with the targets 21₁ to 21₄ of the sputter units 20₁ to 20₄, and is configured to be capable of introducing a mixed gas of the sputtering gas and the reaction gas into the vacuum chamber 11 from the inlet.

A sputter deposition method in which the sputter deposition apparatus 10 is used to form a SiO₂ thin film will now be explained.

First, the following explanation pertains to a step for measuring a protruding minimum value and a protruding maximum value, which are the minimum and maximum amounts that the parts of the outer peripheries of the outer peripheral magnets 27a₁ to 27a₄ of the magnet devices 26₁ to 26₄ of the sputter units 20₁ to 20₄ can protrude out from the outer peripheries of the sputtering surfaces 23₁ to 23₄ of the targets 21₁ to 21₄ of the sputter units 20₁ to 20₄.

In reference to FIGS. 2 and 3, the backing plates 22₁ to 22₄ to which the targets 21₁ to 21₄ of the sputter units 20₁ to 20₄ are attached are carried into the vacuum chamber 11 and placed on the insulators 14. Here, Si is used for the targets 21₁ to 21₄ of the sputter units 20₁ to 20₄.

The adhesion-preventing members 25₁ to 25₄ of the sputter units 20₁ to 20₄ are fixed to the support members 24, and the sputtering surfaces 23₁ to 23₄ of the targets 21₁ to 21₄ of the sputter units 20₁ to 20₄ are exposed on the inside of the rings of the adhesion-preventing members 25₁ to 25₄ of the sputter units 20₁ to 20₄. Here, Al₂O₃ is used for the adhesion-preventing members 25₁ to 25₄ of the sputter units 20₁ to 20₄.

The inside of the vacuum chamber 11 is evacuated by the vacuum evacuation device 12 without carrying the object to be film-deposited 31 into the vacuum chamber 11. Subsequently, a vacuum ambience is maintained inside the vacuum chamber 11 by continuous evacuation.

The mixed gas of the sputtering gas and the reaction gas is introduced into the vacuum chamber 11 from the gas introduction system 13.

Here, Ar gas is used for the sputtering gas, and O₂ gas is used for the reaction gas. The mixed gas is introduced into the vacuum chamber 11 at a flow rate of O₂ gas of a so-called oxide mode which forms an insulating oxide; SiO₂ on the surfaces of the targets 21₁ to 21₄ of the sputter units 20₁ to 20₄ by reaction of the O₂ gas introduced into the vacuum chamber 11 with the surfaces of the targets 21₁ to 21₄ of the sputter units 20₁ to 20₄. Here, Ar gas is introduced with the flow rate of 50 sccm and O₂ gas is introduced with the flow rate of 150 sccm.

The vacuum chamber 11 is brought to grounding potential. When an AC voltage range of 20 kHz to 70 kHz is applied to the backing plates 22₁ to 22₄ of the sputter units 20₁ to 20₄ from the power source device 35, electrical discharge is generated between the adjacent targets 21₁ to 21₄, and the Ar gas above the targets 21₁ to 21₄ of the sputter units 20₁ to 20₄ is ionized and plasmatized.

Ar ions in the plasma are trapped in the magnetic fields formed by the magnet devices 26₁ to 26₄ of the sputter units 20₁ to 20₄. When negative voltages are applied to the backing plates 22₁ to 22₄ of the sputter units 20₁ to 20₄ from the power source device 35, the Ar ions collide into the sputtering surfaces 23₁ to 23₄ of the targets 21₁ to 21₄ on the backing plates 22₁ to 22₄ to which the negative voltages are applied, and SiO₂ formed on the sputtering surfaces 23₁ to 23₄ is stricken off.

A part of the SiO₂ that has been stricken off from the sputtering surfaces 23₁ to 23₄ of the targets 21₁ to 21₄ of the sputter units 20₁ to 20₄ adheres again to the sputtering surfaces 23₁ to 23₄ of the targets 21₁ to 21₄ of the sputter units 20₁ to 20₄.

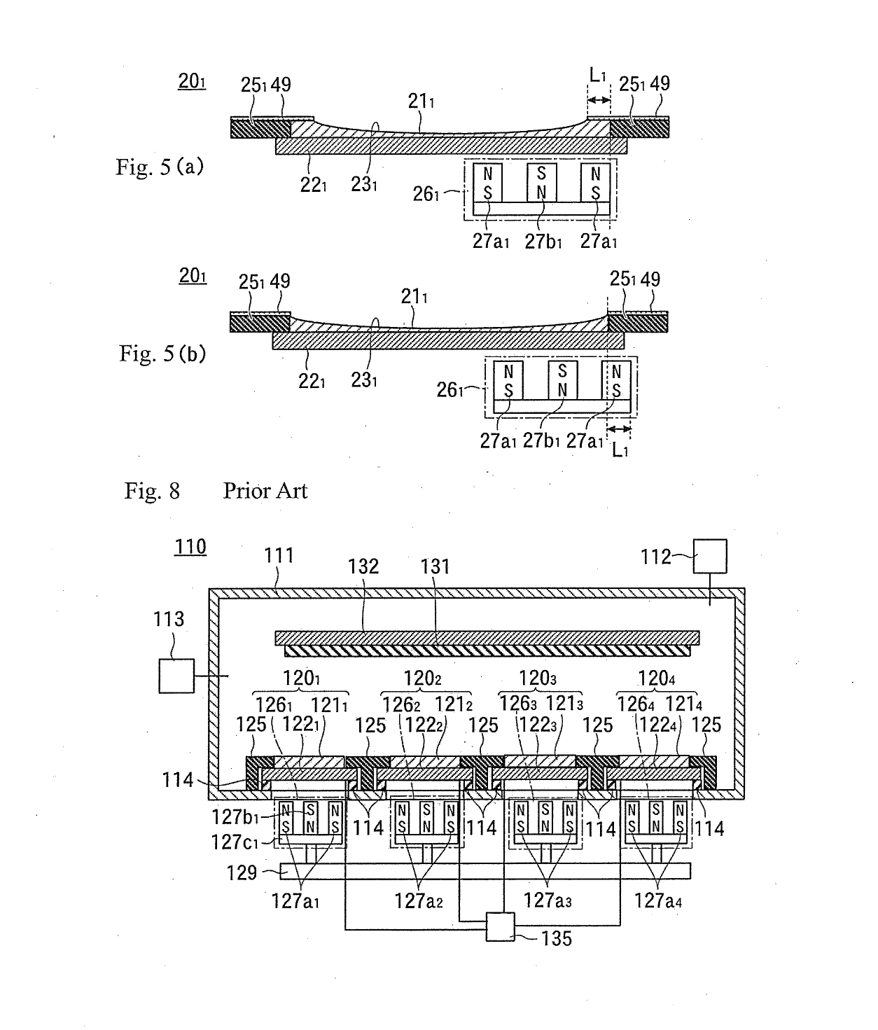

The state of the sputter units 20₁ to 20₄ during sputtering is the same. The following explanation uses the sputter unit associated with reference numeral 20₁ as a representative example. FIG. 5(a) is a schematic view showing a cross-section of the sputtering unit 20₁ during sputtering in the measuring step.

The sputtering surface 23₁ is sputtered while moving the magnet device 26₁ inside a movement range where the entire outer periphery of the outer peripheral magnet 27a₁ is positioned inside of the outer periphery of the sputtering surface 23₁.

When sputtering is continued, the center portion of the sputtering surface 23₁ is sputtered and scraped away to a concave shape. The area of the sputtering surface 23₁, which is sputtered and scraped away, is referred to as an erosion area. SiO₂ particles adhered again accumulate at the non-erosion areas, which are areas outside of the erosion area on the sputtering surface 23₁ that are not sputtered. Reference numeral 49 indicates a thin film of accumulated SiO₂.

The erosion area is scraped away until the outer periphery of the erosion area can be visually confirmed.

Next, the movement range of the magnet device 26₁ is gradually widened and the amount of the part of the outer periphery of the outer peripheral magnet 27a₁ that protrudes to the outside of the outer periphery of the sputtering surface 23₁ is gradually increased, while monitoring the gas composition and the pressure inside the vacuum chamber 11 during evacuation.

As the amount of the portion of the outer periphery of the outer peripheral magnet 27a₁ which protrudes to the outside of the outer periphery of the sputtering surface 23₁ increases, the horizontal component of the magnetic field on the adhesion-preventing member 25₁ increases, and when the adhesion-preventing member 25₁ is scraped away by sputtering, the gas composition during evacuation inside the vacuum chamber 11 changes. When the sputtering of the adhesion-preventing member 25₁ has been confirmed from the change in the gas composition during evacuation inside the vacuum chamber 11, the amount of protrusion of the outer periphery of the outer peripheral magnet 27a₁ from the outer periphery of the sputtering surface 23₁ is measured.

In a producing step (to be explained later), if the adhesion-preventing member 25₁ is scraped away by sputtering, particles of the adhesion-preventing member 25₁ adhere to the surface of the object to be film-deposited 31, and the thin film formed on the surface of the object to be film-deposited 31 becomes contaminated with impurities. Thus, the amount of protrusion measured here is the protruding maximum value.

In the case where the degree of hardness of the adhesion-preventing member 25₁ is so high that it is not sputtered, when a portion of the outer periphery of the outer peripheral magnet 27a₁ protrudes to the inside of the sputtering surface 23₂ of the adjacent target 21₂ and the sputtering surface 23₂ of the adjacent target 21₂ is scraped away, the pressure inside the vacuum chamber 11 changes. When the sputtering of the sputtering surface 23₂ of the adjacent target 21₂ has been confirmed from the change in the pressure inside the vacuum chamber 11, the amount of protrusion of the outer periphery of the outer peripheral magnet 27a₁ from the outer periphery of the sputtering surface 23₁ is measured.

In a producing step (to be explained later), if the sputtering surface 23₂ of the target 21₂ of one sputter unit 20₂ is scraped away by plasma trapped in the magnetic field of the magnet device 26₁ of the adjacent sputter unit 20₁, the planarity of the thin film formed on the surface of the object to be film-deposited 31 decreases. Thus, the amount of protrusion measured here is the protruding maximum value.

Next, in reference to FIG. 3, the application of voltage to the backing plates 22₁ to 22₄ of the sputter units 20₁ to 20₄ is stopped, the introduction of the mixed gas from the gas introduction system 13 is stopped, and sputtering is terminated.

The adhesion-preventing members 25₁ to 25₄ of the sputter units 20₁ to 20₄ are removed from the support members 24; and the targets 21₁ to 21₄ of the sputter units 20₁ to 20₄ are carried to the outside of the vacuum chamber 11 together with the backing plates 22₁ to 22₄.

In reference to FIG. 5(a), the outer periphery of the erosion area is visually confirmed, and an interval L₁ between the outer periphery of the erosion area which has been scraped away by sputtering on the sputtering surface 23₁ and the outer periphery of the sputtering surface 23₁ is found.

A region inside the interval L₁ from the outer periphery of the outer peripheral magnet 27a₁ is scraped away by sputtering, the interval L₁ found here being the protruding minimum value.

A position where a part of the outer periphery of the outer peripheral magnet 27a₁ protrudes to the outside of the outer periphery of the sputtering surface 23₁ by a distance longer than the protruding minimum value, and shorter than the protruding maximum value is stored in the storage device 37.

Next, the producing step will be explained in reference to FIG. 3. The backing plates 22₁ to 22₄ to which unused targets 21₁ to 21₄ of the sputter units 20₁ to 20₄ are attached are carried into the vacuum chamber 11 and placed on the insulators 14.

The adhesion-preventing members 25₁ to 25₄ of the sputter units 20₁ to 20₄ are fixed to the support members 24, and the sputtering surfaces 23₁ to 23₄ of the targets 21₁ to 21₄ of the sputter units 20₁ to 20₄ are exposed on the inside of the rings of the adhesion-preventing members 25₁ to 25₄.

The inside of the vacuum chamber 11 is evacuated by the vacuum evacuation device 12. Subsequently, a vacuum ambience is maintained inside the vacuum chamber 11 by continuous evacuation.

The object to be film-deposited 31 mounted on the object holder 32 is carried into the vacuum chamber 11, and then stopped at a position facing the sputtering surfaces 23₁ to 23₄ of the targets 21₁ to 21₄ with a distance apart form each other.

The mixed gas of sputtering gas and reaction gas is introduced into the vacuum chamber 11 from the gas introduction system 13 at the same flow rate as used in the preparation step discussed above. The surfaces of the targets 21₁ to 21₄ of the sputter units 20₁ to 20₄ react with the O₂ gas, which is the reaction gas, introduced into the vacuum chamber 11 and SiO₂ is formed.

Similar to the preparation step, AC voltages in the range of 20 kHz to 70 kHz are applied to the backing plates 22₁ to 22₄ of the sputter units 20₁ to 20₄ from the power source device 35, the Ar gas, which is the sputtering gas, between the targets 21₁ to 21₄ of the sputter units 20₁ to 20₄ and the object to be film-deposited 31 is plasmatized, and the sputtering surfaces 23₁ to 23₄ of the targets 21₁ to 21₄ of the sputter units 20₁ to 20₄ are sputtered.

Apart of the SiO₂ particles which have been stricken off from the sputtering surfaces 23₁ to 23₄ of the targets 21₁ to 21₄ of the sputter units 20₁ to 20₄ adhere to the surface of the object to be film-deposited 31; and a SiO₂ thin film is formed on the surface of the object to be film-deposited 31.

The state of each of the sputter units 20₁ to 20₄ during sputtering is the same. The following explanation uses the sputter unit associated with reference numeral 20₁ as a representative example.

During sputtering, the magnet device 26₁ of the sputter unit 20₁ is made to repeatedly move between a position where the entire outer periphery of the outer peripheral magnet 27a₁ is on the inside of the outer periphery of the sputtering surface 23₁ of the target 21₁ of the sputter unit 20₁ and the protruding position stored in the storage device 37.

Because the adhesion-preventing member 25₁ is made of an insulating material, abnormal discharge (arcing) does not occur even if the plasma trapped in the magnetic field of the magnet device 26₁ is in contact with the adhesion-preventing member 25₁; and thus, sputtering can be continued.

FIG. 5(b) is a schematic view showing a cross-section of the sputtering unit 20₁ during sputtering in the producing step.

A portion of the outer periphery of the outer peripheral magnet 27a₁ protrudes out from each portion of the entire outer periphery of the sputtering surface 23₁ with a distance longer than the protruding minimum value found in the measuring step. The entire inside of the outer periphery of the sputtering surface 23₁ is scraped away by sputtering; and SiO₂ which adheres again does not accumulate on the sputtering surface 23₁.

In a conventional sputter deposition apparatus, abnormal discharge (arcing) occurred on the target because insulating SiO₂ accumulated on the electrically-conductive target 21₁. However, in the sputter deposition apparatus 10 of the present invention, because SiO₂ does not accumulate on the target 21₁, arcing does not occur on the target 21₁.

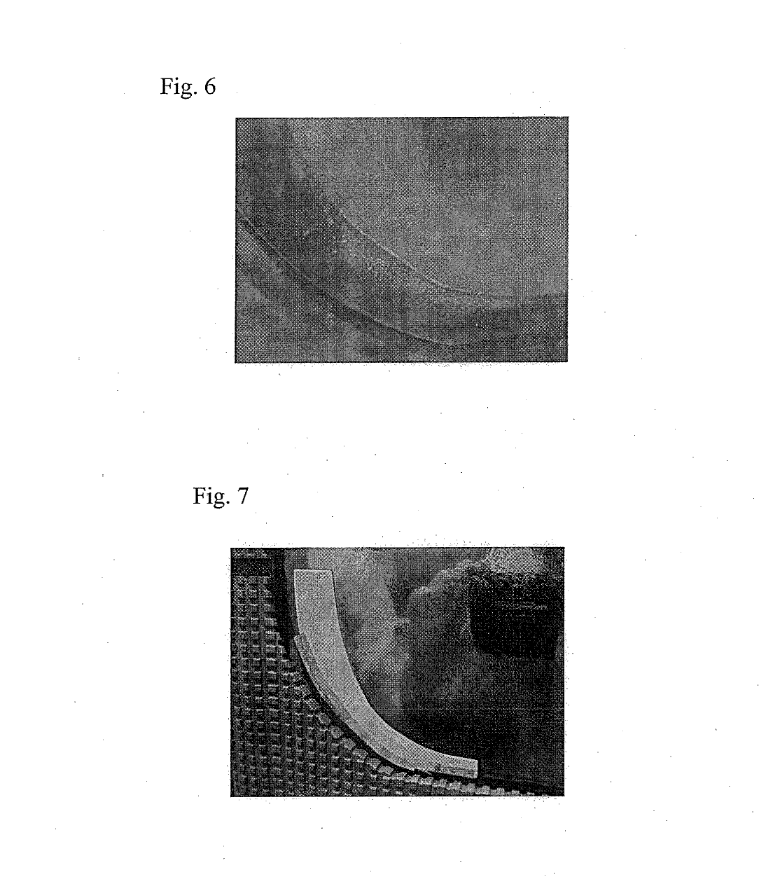

FIG. 6 is a picture showing a corner portion of a target surface after sputtering in a conventional sputter deposition apparatus; and FIG. 7 is a picture showing a corner portion of a target surface after sputtering in the sputter deposition apparatus of the present invention. In FIG. 7, an Al₂O₃ shield member is disposed on the peripheral edge of the target. In FIG. 6, spotted arcing marks can be confirmed in the non-erosion area of the target; however, in FIG. 7, arcing marks cannot be confirmed on the target and it is clear that arcing did not occur.

In the present invention, because arcing does not occur on the target 21₁, damage to the target 21₁ due to arcing can be prevented. Further, contamination due to impurities of the thin film formed on the object to be film-deposited 31 can also be prevented.

Furthermore, the distance to which the outer periphery of the outer peripheral magnet 27a₁ protrudes from the outer periphery of the sputtering surface 23₁ is restricted to a distance which is shorter than the protruding maximum value found in the measuring step. Thus, scraping away by sputtering of the adhesion-preventing member 25₁ can be prevented.

A thin film 49 of SiO₂ which adhered again accumulates on the surface of the adhesion-preventing member 25₁. However, because the adhesion-preventing member 25₁ is made of an insulating material, insulation breakdown due to the accumulated SiO₂ thin film 49 does not occur; and thus, arcing also does not occur on the adhesion-preventing member 25₁.

Because arcing does not occur on the adhesion-preventing member 25₁, damage to the adhesion-preventing member 25₁ due to arcing can be prevented. Furthermore, contamination due to impurities of the thin film formed on the object to be film-deposited 31 can also be prevented.

In reference to FIGS. 2 and 3, sputtering is continued for a predetermined amount of time to form a SiO₂ thin film of a predetermined thickness on the surface of the object to be film-deposited 31. Subsequently, the application of voltage to the backing plates 22₁ to 22₄ of the sputter units 20₁ to 20₄ is stopped, the introduction of the mixed gas from the gas introduction system 13 is stopped, and sputtering is terminated.

The object to be film-deposited 31 is carried to the outside of the vacuum chamber 11 together with the object holder 32 and sent to a post step. Next, an object to be film-deposited 31 upon which a film has not been deposited is placed on the object holder 32 and carried into the vacuum chamber 11, and sputter deposition according to the producing step, as discussed above, is repeated.

Alternatively, the object to be film-deposited 31 on which a film has been deposited is removed from the object holder 32, carried to the outside of the vacuum chamber 11, and sent to a post step. Next, an object to be film-deposited 31 upon which a film has not been deposited is carried into the vacuum chamber 11, placed on the object holder 32, and sputter deposition according to the producing step, as discussed above, is repeated.

In the above explanation, a case in which the sputter deposition apparatus 10 had a plurality of sputter units 20₁ to 20₄ was explained. However, the present invention also includes a case in which there is only one sputter unit.

In the above explanation, O₂ gas was used as the reaction gas. However, the present invention also includes a case in which N₂ gas, or a mixed gas of O₂ gas and N₂ gas, is used as the reaction gas to form an insulating SiOₓN_{y} thin film (x and y are real numbers of 0 or more that satisfy the relationship x+y is greater than 0 and at most 2).

In the above explanation, in reference to FIG. 2, the targets 21₁ to 21₄ of the sputter units 20₁ to 20₄ and the object to be film-deposited 31 faced each other when standing. However, the present invention is not limited to such an arrangement as long as the targets 21₁ to 21₄ of the sputter units 20₁ to 20₄ and the object to be film-deposited 31 are faced toward each other. Thus, they can be made to face each other by arranging the object to be film-deposited 31 above the targets 21₁ to 21₄ of the sputter units 20₁ to 20₄, or they can be made to face each other by arranging the object to be film-deposited 31 below the targets 21₁ to 21₄ of the sputter units 20₁ to 20₄. If the object to be film-deposited 31 is arranged below the targets 21₁ to 21₄ of the sputter units 20₁ to 20₄, particles may fall onto the object to be film-deposited 31, causing the quality of the thin film to deteriorate. Thus, it is preferable to arrange the object to be film-deposited 31 above the targets 21₁ to 21₄ of the sputter units 20₁ to 20₄, or to have the targets 21₁ to 21₄ of the sputter units 20₁ to 20₄ and the object to be film-deposited 31 face each other when standing, as in the embodiment explained above.

In FIG. 1, the planar shape of the magnet devices 26₁ to 26₄ is represented as a long and narrow shape, but the planar shape of the magnet devices 26₁ to 26₄ of the present invention is not limited to a long and narrow shape.

### EXPLANATION OF THE REFERENCE NUMERALS

10 . . . sputter deposition apparatus
11 . . . vacuum chamber
12 . . . vacuum evacuation device
13 . . . gas introduction system
20₁ to 20₄ . . . sputter unit
21₁ to 21₄ . . . target
25₁ to 25₄ . . . adhesion-preventing member
26₁ to 26₄ . . . magnet device
27a₁ . . . outer peripheral magnet
27b₁ . . . center magnet
29 . . . moving device
31 . . . object to be film-deposited
35 . . . power source device

What is claimed is:

1. A sputter deposition apparatus, comprising:
a vacuum chamber;
a vacuum evacuation device evacuating the inside of the vacuum chamber;
a gas introduction system introducing gas into the vacuum chamber;
a target having a sputtering surface exposed inside the vacuum chamber;
an adhesion-preventing member disposed inside the vacuum chamber and provided to the target so as to surround a periphery of the sputtering surface of the target;
a magnet device arranged on a rear surface side opposite to the sputtering surface of the target;
a power source device applying a voltage to the target; and
a moving device which moves the magnet device in a direction parallel to the rear surface of the target,
wherein the magnet device has a substantially ring-shaped outer peripheral magnet which faces toward the rear surface of the target and a center magnet disposed on the inside of the ring formed by the outer peripheral magnet,
wherein a polarity of a magnetic pole of a portion at which the outer peripheral magnet faces toward the rear surface of the target and a polarity of a magnetic pole of a portion at which the center magnet faces toward the rear surface of the target are different from each other,
wherein the adhesion-preventing member is formed of an insulating ceramic, and
wherein the moving device moves the magnet device between a position where the entire outer periphery of the outer peripheral magnet is on the inside of the outer periphery of the sputtering surface and another position where a part of the outer periphery of the outer peripheral magnet protrudes to the outside of the outer periphery of the sputtering surface.

2. The sputter deposition apparatus according to claim 1, wherein the target is Si, and the gas introduction system has an O₂ gas source which releases O₂ gas.

3. The sputter deposition apparatus according to claim 1, further comprising:
a plurality of sputter units which include the target, the adhesion-preventing member provided to the target, and the magnet device disposed on the rear surface side of the target,
wherein the targets of the sputter units are arranged in a line spaced apart from each other, each sputtering surface being oriented toward an object to be film-deposited carried into the vacuum chamber,
wherein the power source device applies a voltage to the target of each sputter unit, and
wherein the moving device moves the magnet device of one sputter unit between a position where the entire outer periphery of the outer peripheral magnet of the magnet device is on the inside of the outer periphery of the sputtering surface of the target of the sputter unit and a position where a part of the outer periphery of the outer peripheral magnet protrudes out between the outer periphery of the sputtering surface of the target and the outer periphery of the sputtering surface of the target of another sputter unit adjacent to the target.

4. The sputter deposition apparatus according to claim 2, further comprising:
a plurality of sputter units which include the target, the adhesion-preventing member provided to the target, and the magnet device disposed on the rear surface side of the target,
wherein the targets of the sputter units are arranged in a line spaced apart from each other, each sputtering surface being oriented toward an object to be film-deposited carried into the vacuum chamber,
wherein the power source device applies a voltage to the target of each sputter unit, and
wherein the moving device moves the magnet device of one sputter unit between a position where the entire outer periphery of the outer peripheral magnet of the magnet device is on the inside of the outer periphery of the sputtering surface of the target of the sputter unit and another position where a part of the outer periphery of the outer peripheral magnet protrudes out between the outer periphery of the sputtering surface of the target and the outer periphery of the sputtering surface of the target of another sputter unit adjacent to the target.
